(19) United States
(12) Patent Application Publication
(10) Pub. No.: US 2014/0063759 A1
(43) Pub. Date: Mar. 6, 2014

(54) DRIP-PROOF STRUCTURE OF ELECTRONIC APPARATUS

(71) Applicant: FANUC Corporation, Minamitsuru-gun (JP)

(72) Inventor: Yuuichi HONDA, Minamitsuru-gun (JP)

(73) Assignee: FANUC Corporation, Minamitsuru-gun (JP)

(21) Appl. No.: 14/013,056

(22) Filed: Aug. 29, 2013

(30) Foreign Application Priority Data
Sep. 3, 2012 (JP) 2012-193285

(51) Int. Cl. H05K 5/02

(52) U.S. Cl. CPC H05K 5/0234
USPC 361/752

(57) ABSTRACT

A drip-proof structure of an electronic apparatus in which a printed circuit board is fixed to a stud provided on a housing includes a concave portion and/or a convex portion that is provided around the stud on the housing. Therefore, when a liquid, such as a cutting fluid, flows on the housing, the flow of the liquid from the stud to the printed circuit board is prevented by the concave portion and/or the convex portion.

### BACKGROUND OF THE INVENTION

1. Field of the Invention

The present invention relates to a drip-proof structure that is used for an electronic apparatus in which a printed circuit board is fixed to a stud provided on a housing and is capable of preventing a liquid, such as a cutting fluid which flows on the housing, from flowing from the stud to the printed circuit board.

2. Description of the Related Art

An electronic apparatus, such as a numerical controller for controlling a machine tool, is attached to, for example, a control panel housing of the machine tool and is used in a severe factory environment using the cutting fluid. In general, a structure has been used in which studs are provided on a housing of an electronic apparatus in order to support a printed circuit board and the printed circuit board is fixed to the studs by screws (for example, see Japanese Patent Application Laid-Open No. 10-301613).

In order to protect the inside of the control panel housing from the factory environment, a structure has been used in which a packing is provided between the control panel housing and the electronic apparatus, such as the numerical controller, or at an inlet through which a cable is inserted into the control panel housing such that outdoor air or a cutting fluid is not infiltrated into the control panel housing.

However, in some cases, the packing deteriorates in a severe environment in which a large amount of cutting fluid is continuously used or over time and the cutting fluid is infiltrated into the control panel housing. In this case, a liquid, such as a cutting fluid, flows on the housing of the electronic apparatus and is then spread from the stud to the printed circuit board. As a result, problems, such as a pattern short of the printed circuit board and a reduction in the lifespan of an electronic component, arise.

FIG. 9 is a diagram illustrating an example of an electronic apparatus according to the related art. A cutting fluid flows on the surface of a housing 5 of the electronic apparatus in a direction represented by reference numeral 11 and is spread to the outer circumference of a stud 8 provided on the housing 5 or is infiltrated into the stud 8 from the base of the stud 8. The cutting fluid which has flowed to the outer circumference of the stud 8 is spread onto the surface of a printed circuit board 7. On the other hand, the cutting fluid which has infiltrated into the stud 8 is spread onto the surface of the printed circuit board 7 which is fixed to the studs 8 by screws 6.

### SUMMARY OF THE INVENTION

The invention has been made in view of the problems of the related art and an object of the invention is to provide a drip-proof structure of a housing of an electronic apparatus in which a printed circuit board having an electronic component mounted thereon is fixed to a stud provided on the housing, a concave portion and/or a convex portion is formed around the stud on the housing, and the flow of a liquid, such as a cutting fluid, from the stud to the printed circuit board is prevented when the liquid flows on the housing.

According to a drip-proof structure of the invention, a concave portion and/or a convex portion is formed around a stud which supports a printed circuit board on a housing of an electronic apparatus so as to surround the stud. A liquid which has flowed on the housing is guided to flow along the outer edge of the concave portion and/or the convex portion. Therefore, the amount of liquid flowing from the stud to the printed circuit board is significantly reduced.

A large number of electronic components are mounted on the printed circuit board which is attached to the housing of the electronic apparatus and air is drawn into a control panel housing on which the electronic apparatus is mounted by, for example, a fan in order to effectively dissipate heat generated from the electronic components. In this case, since air flows around the stud, it is assumed that the liquid which has flowed to the housing of the electronic apparatus flows in the horizontal direction of the housing of the electronic apparatus or a direction from the lower side to the upper side, in addition to the direction from the upper side to the lower side. In order to respond to the flow of the liquid, the concave portion and/or the convex portion surrounds the entire circumference of the stud without a break. Therefore, it is possible to obtain the same drip-proof effect even when the liquid flows in any direction.

The drip-proof structure according to the present invention is applied to an electronic apparatus in which a printed circuit board is fixed to a plurality of studs provided on a housing. In a drip-proof structure of the electronic apparatus, a concave portion and/or a convex portion is provided around the stud on the housing of the electronic apparatus.

The concave portion and/or the convex portion which is provided around the stud on the housing may surround the stud without a break.

According to the present invention, it is possible to provide a drip-proof structure of a housing of an electronic apparatus in which a printed circuit board having an electronic component mounted thereon is fixed to studs provided on the housing, a concave portion and/or a convex portion is formed around the stud on the housing, and the flow of a liquid, such as a cutting fluid, from the stud to the printed circuit board is prevented when the liquid flows on the housing.

### BRIEF DESCRIPTION OF THE DRAWINGS

The forgoing and other objects and feature of the invention will be apparent from the following description of preferred embodiments of the invention with reference to the accompanying drawings, in which:

FIG. 1 is a perspective view illustrating the outward appearance of an electronic apparatus;

FIG. 2 is a cross-sectional view illustrating the electronic apparatus taken along the line A-A of FIG. 1;

FIG. 3 is a perspective view illustrating the electronic apparatus shown in FIG. 2, as viewed from the direction of an arrow C;

FIG. 4 is a diagram illustrating a concave/convex structure portion which is provided around a stud;

FIG. 5 is a diagram illustrating the concave/convex structure portion which is provided so as to surround the stud on the housing without a break;

FIG. 6 is a diagram illustrating a first example of the concave/convex structure portion forming a drip-proof structure according to the present invention;

FIG. 7 is a diagram illustrating a second example of the concave/convex structure portion forming the drip-proof structure according to the present invention;

FIG. 8 is a diagram illustrating a third example of the concave/convex structure portion forming the drip-proof structure according to the present invention; and

FIG. 9 is a cross-sectional view illustrating an electronic apparatus according to the related art.

### DETAILED DESCRIPTION OF THE PREFERRED EMBODIMENTS

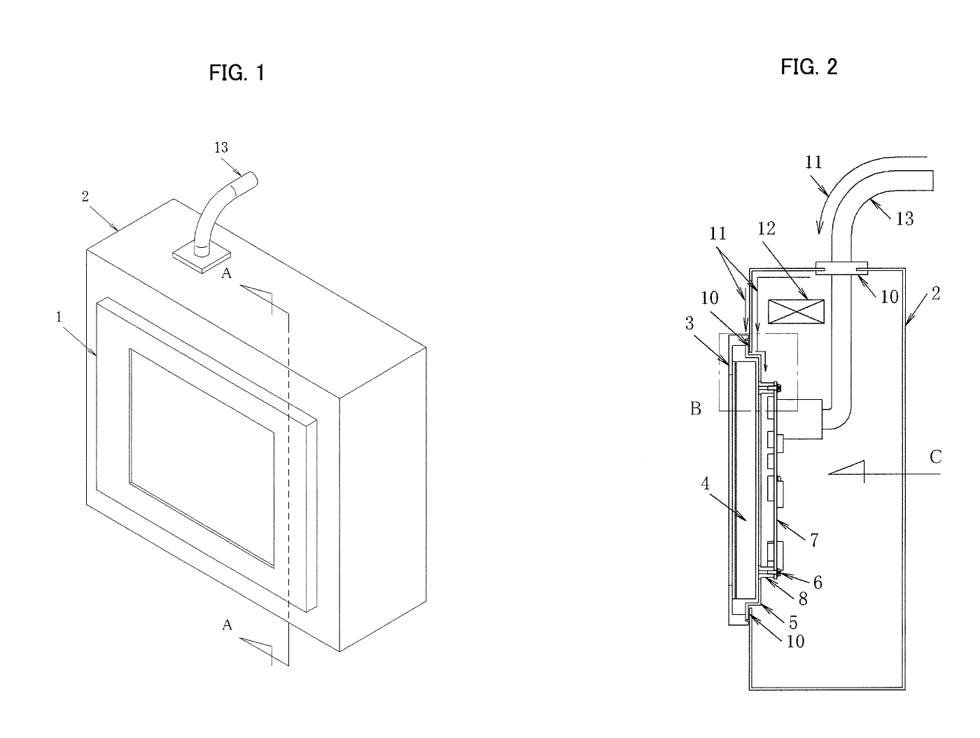

FIG. 1 shows an electronic apparatus 1, such as a numerical controller for controlling a machine tool, and a control panel housing 2 for the machine tool to which the electronic apparatus 1 is attached. A cable 13 extends from the inside of the control panel housing 2 to the outside. In the following description, for example, the electronic apparatus 1 is a numerical controller for controlling the machine tool.

As shown in FIG. 2 which is a cross-sectional view taken along the line A-A of FIG. 1, the electronic apparatus 1 (that is, the numerical controller) includes a liquid crystal panel 4, a housing 5 to which the liquid crystal panel 4 is attached, a front cover 3 which covers a display surface of the liquid crystal panel 4, a plurality of studs 8 which are provided on a surface of the housing 5 opposite to the surface on which the liquid crystal panel 4 is provided, and a printed circuit board 7 which is supported by the studs 8 and are fixed by screws 6.

Various electronic components (not shown) are mounted on the printed circuit board 7. The liquid crystal panel 4 is connected to a control circuit which is formed by the electronic components mounted on the printed circuit board 7 by wires (not shown) and the display operation of the liquid crystal panel 4 is controlled by the control circuit. The control circuit provided on the printed circuit board 7 is connected to the cable 13 through a connection terminal (not shown) provided on the printed circuit board 7. Although not shown in the drawings, the other end of the cable 13 is connected to, for example, an amplifier for driving a motor which is a driving unit of the machine tool.

The electronic apparatus 1 is attached to an opening portion which is provided in one surface of the control panel housing 2. The housing 5 of the electronic apparatus 1 includes a concave portion for mounting the liquid crystal panel 4 and a brim-shaped edge portion which is formed around the concave portion. The liquid crystal panel 4 is fixed to the concave portion of the housing 5 by fixing members (not shown) such as screws. The brim-shaped edge portion which is formed around the concave portion of the housing 5 is fixed to an outer circumferential portion of the opening portion provided in the control panel housing 2 by fixing members (not shown) , such as screws, through a sealing member, such as a packing 10. In addition, the front cover 3 is fixed to the housing 5 by fixing members (not shown) such as screws.

In order to protect the inside of the control panel housing 2 from a factory environment, the packing 10 is provided between the control panel housing 2 and the electronic apparatus 1 or at an inlet through which the cable 13 is inserted into the control panel housing 2 such that outdoor air or a cutting fluid is not infiltrated into the control panel housing 2. A fan 12 is attached to the wall surface of the control panel housing 2 to cool the inside of the control panel housing 2.

In the drip-proof structure of the housing of the electronic apparatus according to the present invention, the printed circuit board 7 having the electronic components mounted thereon is fixed to the studs 8 provided on the housing 5 of the electronic apparatus 1 and concave portions and/or convex portions 9 are provided around the studs 8 on the housing 5. Therefore, when a liquid, such as a cutting fluid, flows into the housing 5, the flow of the liquid from the stud 8 to the printed circuit board 7 is prevented.

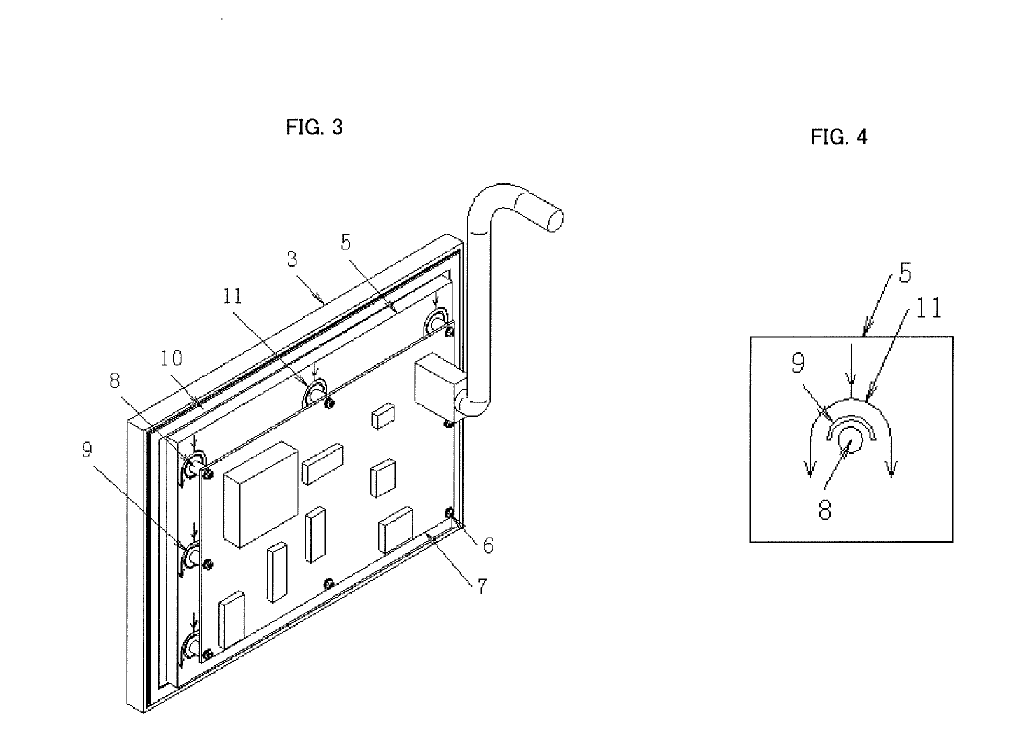

An example in which the drip-proof structure according to the present invention is applied to the housing 5 of the electronic apparatus 1 shown in FIG. 2 will be described with reference to FIG. 3 (a perspective view illustrating the electronic apparatus 1 shown in FIG. 2, as viewed from the direction of an arrow C).

The printed circuit board 7 having the electronic components mounted thereon is fixed to the leading end of each of the plurality of studs 8 by the screws 6. Concave portions and/or the convex portions are provided around the studs 8 provided on the housing 5. Hereinafter, the concave portions and/or the convex portions provided around the studs 8 on the housing 5 are referred to as concave/convex structure portions 9.

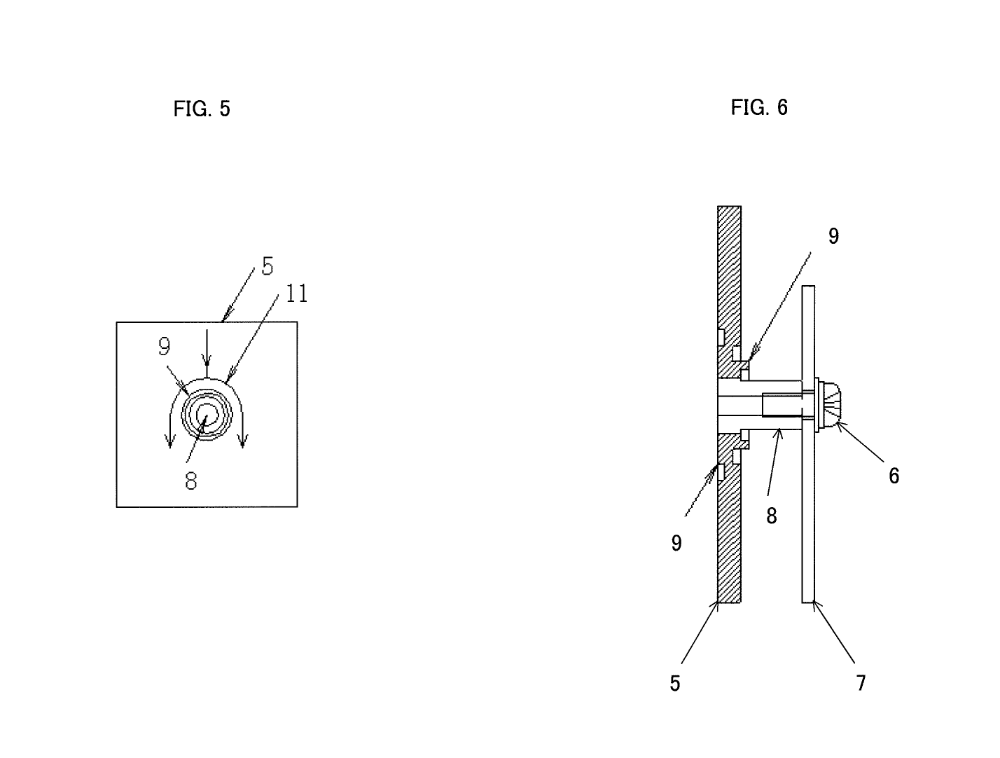

Since the concave/convex structure portions 9 (see FIG. 4) are provided around the studs 8 on the housing 5, a liquid (see a liquid flow 11) flows along the concave/convex structure portion 9 on the housing 5. Therefore, the liquid is less likely to flow from the stud 8 to the printed circuit board 7. When the concave/convex structure portion 9 is formed so as to surround the entire circumference of the stud 8 without a break (that is, as shown in FIG. 5, when the concave/convex structure portion 9 is formed in an annular shape), it is possible to constantly obtain a sufficient drip-proof effect even when the liquid which has flowed on the housing 5 of the electronic apparatus 1 flows in the horizontal direction or a direction from the lower side to the upper side by, for example, the direction of the wind around each stud 8. The concave/convex structure portion 9 provided around the stud 8 on the housing 5 may be a concave portion and/or a convex portion. That is, the concave/convex structure portion 9 may be only a convex portion or only a concave portion, or a convex portion may be formed around a given stud 8 and a concave portion may be formed around another stud 8 on the housing 5, considering an obstacle or space problem around each stud 8.

In the present invention, a plurality of studs 8 for fixing the printed circuit board 7 are provided on the housing 5 of the electronic apparatus 1 and the concave/convex structure portion 9 is provided around each stud 8 on the housing 5, as shown in FIG. 4. Therefore, when the printed circuit board 7 is fixed to the studs 8, the electronic apparatus is drip-proofed. The concave/convex structure portion 9 provided around the stud 8 on the housing 5 is a ridge-shaped convex portion and/or a groove-shaped concave portion. The concave/convex structure portion 9 provided on the housing 5 prevents the liquid (see the liquid flow 11 in FIG. 4) which has flowed on the surface of the housing 5 from flowing in a direction parallel to the central axis of the stud 8.

The concave/convex structure portion 9 shown in FIG. 4 is formed in half (upper half) of the circumference of the stud 8, not formed in the entire circumference of the stud 8 on the housing 5, since it is not assumed that a liquid flows on the housing 5 from the lower side to the upper side. The concave/convex structure portion 9 shown in FIG. 5 is formed around the stud 8 on the housing 5 without a break (that is, the concave/convex structure portion 9 is formed so as to surround the entire circumference of the stud 8) . In some cases, in the control panel housing 2, the liquid which has flowed on the housing 5 flows to the stud 8 in all directions, that is, from the left side to the right side, from the right side to the left side, from the upper side to the lower side, and from the lower side to the upper side by air conditioning. In this case, as shown in FIG. 5, since the concave/convex structure portion 9 is formed so as to surround the entire circumference of the stud 8 on the housing 5, it is possible to prevent the flow of a liquid on the housing 5 in any direction.

Some examples of the concave/convex structure portion 9 will be described with reference to FIGS. 6 to 8 which are enlarged views illustrating a portion surrounded by a one-dot chain line represented by letter B in FIG. 2.

In the concave/convex structure portion 9 shown in FIG. 6, an annular concave portion and an annular convex portion are formed on a surface of the housing 5 having the stud 8 provided thereon so as to surround the stud 8 and a concave portion is formed in a surface opposite to the surface on which the stud 8 is formed. The concave portion forming the concave/convex structure portion 9 has a groove shape which is recessed from the plane of the housing 5 and the convex portion forming the concave/convex structure portion 9 has a ridge shape which protrudes from the plane of the housing 5.

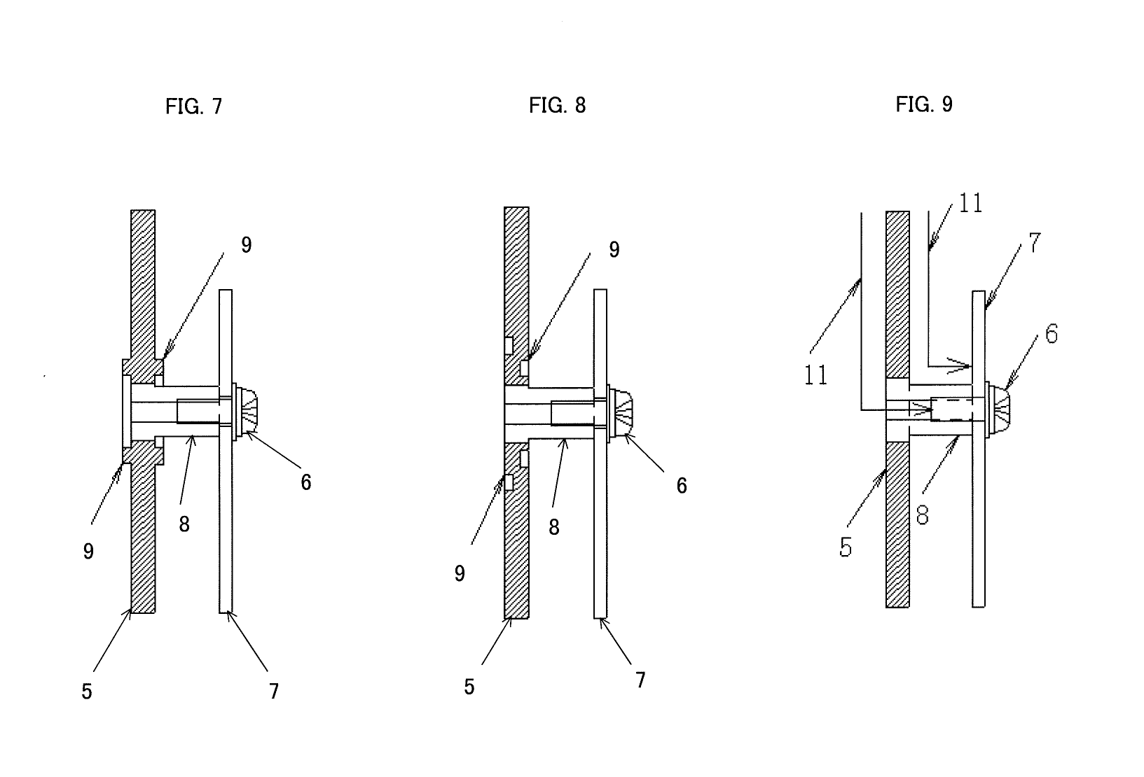

In the concave/convex structure portion 9 shown in FIG. 7, an annular convex portion is formed on a surface of the housing 5 having the stud 8 provided thereon so as to surround the stud 8 and a convex portion is formed on a surface opposite to the surface on which the stud 8 is formed. The convex portions forming the concave/convex structure portion 9 have a ridge shape which protrudes from the plane of the housing 5.

In the concave/convex structure portion 9 shown in FIG. 8, an annular concave portion is formed in a surface of the housing 5 having the stud 8 provided thereon so as to surround the stud 8 and a concave portion is formed in a surface opposite to the surface on which the stud 8 is formed. The concave portions forming the concave/convex structure portion 9 have a groove shape which is recessed from the plane of the housing 5. The amount of liquid flowing on the housing 5 is not large. Therefore, when the groove-shaped concave portion is formed around the stud 8, the liquid which flows on the housing 5 is not infiltrated into the concave portion by the surface tension of the edge of the groove-shaped concave portion. The liquid flows along the edge of the groove-shaped concave portion.

In the above description, the numerical controller for controlling the machine tool is given as an example of the electronic apparatus 1 to the drip-proof structure according to which the present invention is applied. However, application of the drip-proof structure according to the present invention is not limited to numerical controllers for controlling a machine tool, but the drip-proof structure according to the present invention can be applied to various technical fields in which inflow of various kinds of liquid into a housing to which an electronic apparatus including a printed circuit board supported by studs is attached is considered.

1. A drip-proof structure of an electronic apparatus in which a stud is provided on a housing and a printed circuit board is fixed to the stud, the drip-proof structure comprising:
a concave portion and/or a convex portion that is provided around the stud on the housing.

2. The drip-proof structure of the electronic apparatus according to claim 1,
wherein the concave portion and/or the convex portion that is provided around the stud on the housing surrounds the stud without a break.
